(19) United States
(12) Patent Application Publication
(10) Pub. No.: US 2010/0105173 A1
(43) Pub. Date: Apr. 29, 2010

(54) METHOD OF PRODUCING SEMICONDUCTOR DEVICE PROVIDED WITH FLIP-CHIP MOUNTED SEMICONDUCTOR ELEMENT

(75) Inventor: Joji Fujimori, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/603,081

(22) Filed: Oct. 21, 2009

(30) Foreign Application Priority Data
Oct. 29, 2008 (JP) 2008-277854

(51) Int. Cl. H01L 21/60

(52) U.S. Cl. 438/121; 257/E21.511

(57) ABSTRACT

A method for manufacturing a semiconductor device by mounting a semiconductor element on a circuit board, the semiconductor element having a first electrode made of a first material on a semiconductor substrate, the circuit board having a second electrode made of a second material on an insulating substrate, the method includes
forming a connecting member on the first electrode, a melting point of the connecting member being lower than a melting point of the first material,
placing the semiconductor element on the circuit board, so as to face the connecting member toward the second electrode, and
connecting the first electrode and the second electrode, so as to interpose the connecting member between the first electrode and the second electrode, at a temperature that is lower than the melting point of the first material and higher than the melting point of the connecting member.

### CROSS-REFERENCE TO RELATED APPLICATIONS

This application is based upon and claims the benefit of priority of the prior Japanese Patent Application No. 2008-277854, filed on Oct. 29, 2008 the entire contents of which are incorporated herein by reference.

### FIELD

The described embodiments relate to a semiconductor device producing method, particularly to a semiconductor device producing method in which a semiconductor element is formed in a flip-chip mounting manner on a circuit board.

### BACKGROUND

When the semiconductor element is mounted on the circuit board to form the semiconductor device, a so-called flip-chip connection (face-down connection) structure is adopted as one of means for mounting the semiconductor element. In the flip-chip connection structure, a principal surface of the semiconductor element is mounted while facing the circuit board.

A projected electrode such as a solder bump provided in a semiconductor element and an electrode terminal provided on the circuit board are directly connected to each other in the flip-chip connection method.

On the other hand, in order to avoid an adverse effect on the environment, use of a so-called lead-free solder is becoming mainstream as a material of the solder bump constituting the projected electrode.

In the semiconductor element, higher integration is required in order to meet a need of multi-function and miniaturization. Therefore, a low-dielectric insulating material (so-called Low-k material) is adopted as an inter-layer insulating material of a wiring layer in order to satisfy a narrower pitch of the wiring, high density, and a high operating speed.

For example, in a technique disclosed in Japanese Laid-open Patent Publication No. 2006-324642, the low-dielectric insulating layer is adopted as the inter-layer insulating layer in the wiring layer of the semiconductor element, and the wiring layer and a via are provided in the low-dielectric insulating layer.

However, depending on a type of the lead-free solder, sometimes the semiconductor element and the circuit board are heated to about 300° C. during a reflow treatment.

Therefore, when the semiconductor element and the circuit board are cooled from the high temperature in the reflow state to a room temperature, a strong stress is applied onto the semiconductor element side because a thermal expansion coefficient of the semiconductor element is smaller than a thermal expansion coefficient of the circuit board.

Particularly, because a creep phenomenon is hardly generated in the lead-free solder, the stress is not absorbed in the solder bump, but the stress is concentrated on the semiconductor element side.

When the low-dielectric insulating layer is adopted as the inter-layer insulating layer in the semiconductor element, the stress is concentrated on the semiconductor element side to generate breakage or peel-off of the low-dielectric insulating layer, and possibly a short circuit and/or disconnection is generated in a wiring layer and an inter-layer connection portion, which are provided in the inter-layer insulating layer.

In the method of connecting the solder bump made of the lead-free solder provided in the semiconductor element and the electrode provided in the circuit board, unfortunately there is a high possibility of lowering a production yield of the semiconductor device or reliability.

When a lead-free solder having a lower melting point is used as the solder bump material, because the reflow treatment temperature may be set lower, it is predicted that the thermal expansion is suppressed in the semiconductor element and the circuit board.

However, when solder material having the low melting point is used, sometimes the solder bump itself is melted by heat generated in operating the semiconductor device, which results in the degradation of the reliability of the semiconductor device.

### SUMMARY

An aspect of the embodiments, is a method for manufacturing a semiconductor device by mounting a semiconductor element on a circuit board, the semiconductor element having a first electrode made of a first material on a semiconductor substrate, the circuit board having a second electrode made of a second material on an insulating substrate, the method includes forming a connecting member on the first electrode, wherein a melting point of the connecting member is lower than a melting point of the first material, placing the semiconductor element on the circuit board, so as to face the connecting member toward the second electrode, and connecting the first electrode and the second electrode, so as to interpose the connecting member between the first electrode and the second electrode, at a temperature that is lower than the melting point of the first material and higher than the melting point of the connecting member.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a flowchart illustrating a producing process according to a first embodiment;

FIGS. 2A-2F are sectional schematic diagrams of a main part explaining a semiconductor device producing method of the first embodiment;

FIGS. 3A-3E are sectional schematic diagrams of a main part explaining a semiconductor device producing method according to a second embodiment;

FIGS. 4A-4E are sectional schematic diagrams of a main part explaining a semiconductor device producing method according to a third embodiment;

FIGS. 5A-5B are sectional schematic diagrams of a main part explaining a semiconductor device producing method according to a fourth embodiment;

FIGS. 6A-6B are sectional schematic diagrams of a main part explaining a semiconductor device producing method according to a fifth embodiment; and

FIGS. 7A-7F are sectional schematic diagrams of a main part explaining a semiconductor device producing method according to a seventh embodiment.

### DETAILED DESCRIPTION OF THE EMBODIMENTS

Hereinafter a semiconductor producing method according to embodiments of the invention will be described with reference to the drawings.

### First Embodiment

A semiconductor producing method according to a first embodiment of the invention will be described below.

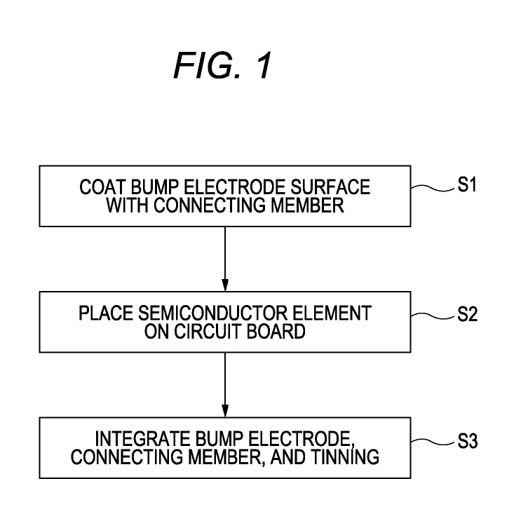

FIG. 1 is a flowchart illustrating a producing process of the first embodiment.

In the first embodiment, first a semiconductor element and a circuit board are prepared. In the semiconductor element, a bump electrode (solder bump) is provided on one of principal surfaces of a semiconductor substrate. In the circuit board, a tinning layer (conductive layer) is formed on an electrode pad (electrode terminal).

At least a part of a surface of the bump electrode provided in one of the principal surfaces of the semiconductor element is coated with a connecting member made of a solder material whose melting point is lower than those of the bump electrode and tinning layer (Step S1).

The semiconductor element is placed face down on the circuit board such that the bump electrode of the semiconductor element and the tinning layer provided in the surface of the electrode pad in the circuit board are brought into contact with each other with the connecting member interposed therebetween (Step S2).

A reflow treatment is performed to melt the connecting member at a temperature at which the connecting member is melted, thereby integrating the bump electrode, the connecting member, and the tinning layer (Step S3).

That is, the semiconductor element is mounted on the circuit board by a flip-chip connection method.

In the first embodiment, the bump electrode including the solder bump provided in one of the principal surfaces of the semiconductor element and the electrode provided in the circuit board are connected by the solder material having a melting point lower than the solder bump.

In the producing process, compared with the case in which the bump electrode and the electrode pad in which the tinning layer is provided are directly connected and integrated, a reflow treatment temperature may be lowered, and the short circuit and disconnection of the wiring layer and inter-layer connection portion, which are provided in the insulating layer, are prevented without generating the breakage or peel-off of the insulating layer provided in the principal surface of the semiconductor element.

Therefore, the semiconductor device having high reliability may be produced with a high production yield.

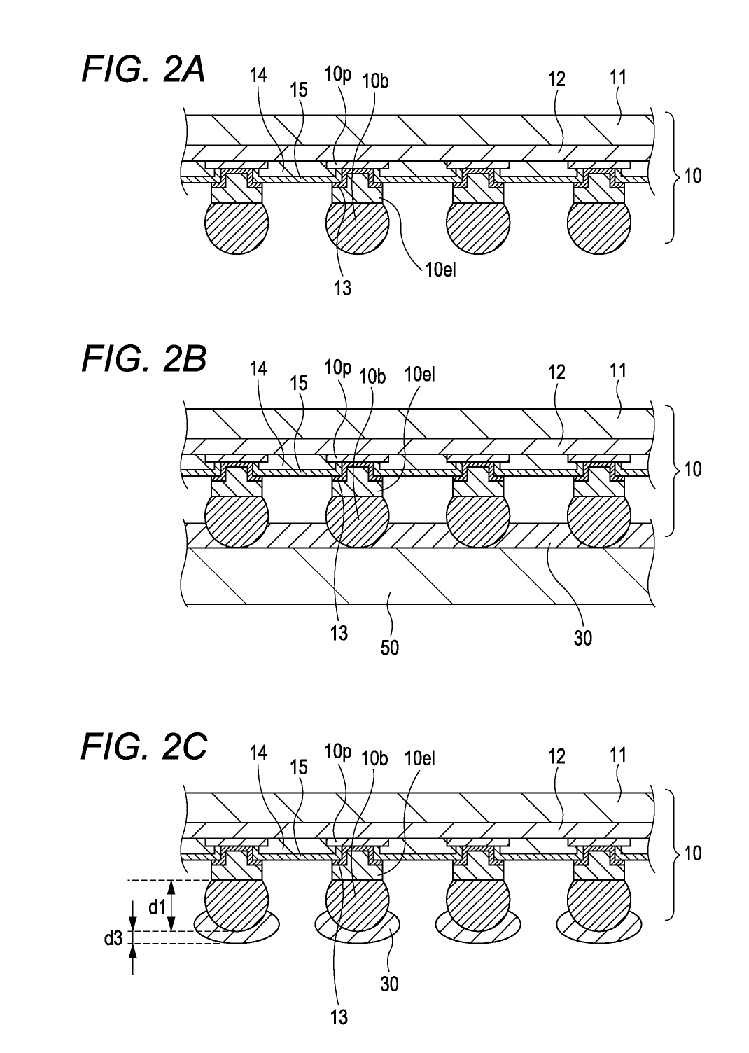

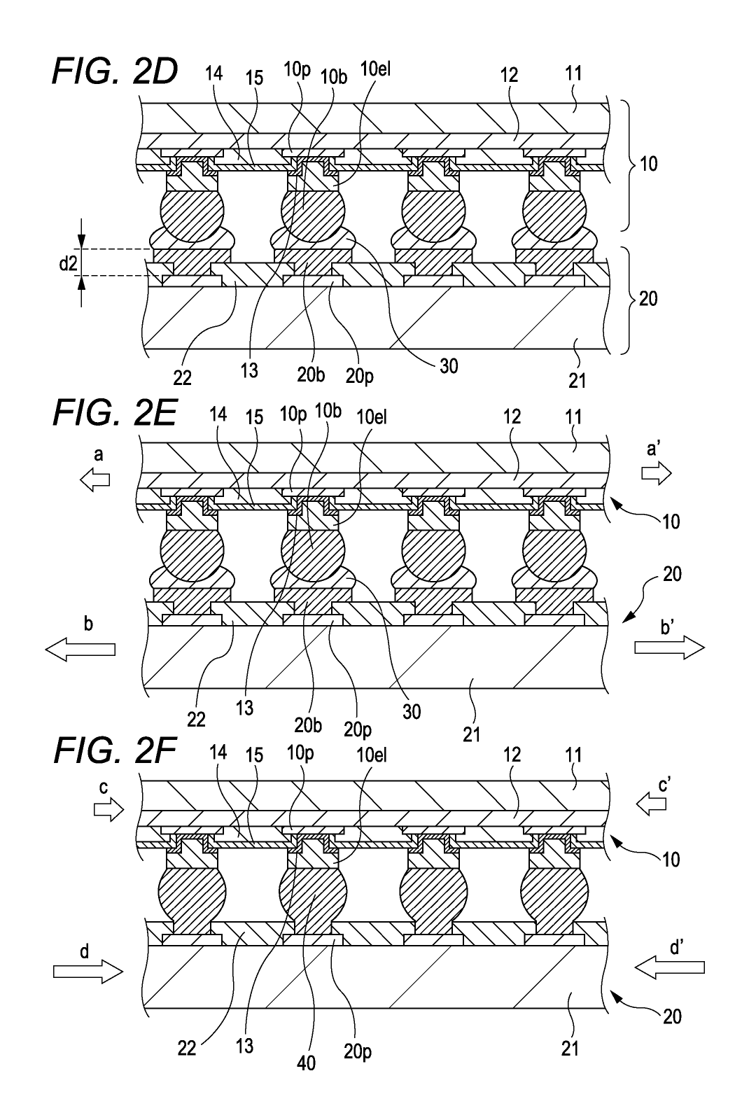

The semiconductor device producing method of the first embodiment including a process for flip-chip mounting the semiconductor element on the circuit board will be described in more detail with reference to FIGS. 2A-2F.

FIGS. 2A-2F are sectional schematic diagrams of a main part explaining the semiconductor device producing method of the first embodiment.

FIG. 2A illustrates a semiconductor element 10 used in the first embodiment.

In the semiconductor element 10, an electronic circuit is formed in one of principal surfaces of a semiconductor substrate 11 by a so-called wafer process. The electronic circuit includes an active element such as a transistor, a passive element such as a capacitance element, and a wiring layer and an inter-layer connection portion that connect the functional elements to each other.

The wiring layer and the inter-layer connection portion are disposed in a low-dielectric insulating layer 12 while a so-called multi-layer wiring layer is formed by the wiring layer and the inter-layer connection portion. The low-dielectric insulating layer 12 is formed in the principal surface of the semiconductor substrate 11.

In the semiconductor element 10, plural electrode pads 10p electrically connected to the wiring layer are directly provided on the low-dielectric insulating layer 12, or the plural electrode pads are provided on the low-dielectric insulating layer 12 with an inorganic insulating layer interposed therebetween. A columnar electrode 10el is provided on each of the electrode pads 10p. A bump electrode (solder bump) 10b that is of an external connecting electrode is provided on the columnar electrode 10e1.

A metallic layer 13 is provided between the columnar electrode 10el and the electrode pad 10p such that a solder component of the bump electrode 10b is suppressed and prevented from diffusing in the electrode pad 10p.

The low-dielectric insulating layer 12 and part of the electrode pad 10p are coated with an inorganic insulating layer 14, and the inorganic insulating layer 14 is coated with an organic insulating layer 15.

The metallic layer 13 is extended onto the organic insulating layer 15.

In the semiconductor element 10, a well-known semiconductor material such as silicon (Si) and gallium arsenide (GaAs) may be used as the semiconductor substrate 11.

A porous inorganic insulating material or a porous organic insulating material is used as the low-dielectric insulating layer 12. That is, any of Fluorine-doped Silicon Glass (FSG), silicon oxide-carbide (SiOC), silicon dioxide (SiO₂), and organic resin may be used as the low-dielectric insulating layer 12.

A well-known metal, such as one mainly containing aluminum (Al) or copper (Cu) may be used as the electrode pad 10p. A planar shape of the electrode pad 10p is a circular shape having a diameter of 50 μm to 150 μm, and the electrode pads 10p are provided at intervals of 100 μm to 250 μm.

A metal mainly containing copper (Cu) may be used as the columnar electrode 10el. In the columnar electrode 10el, a plating layer may be provided in the surface on the side of the bump electrode 10b in order to suppress a solder diffusion reaction into the electrode 10el. In the plating layer, nickel (Ni) and gold (Au) are sequentially deposited on a lower layer.

On the other hand, titanium (Ti) or metal mainly containing titanium nitride (TiN) or titanium carbide (TiC) may be used as the metallic layer 13.

Silicon oxide (SiO₂) or silicon nitride (Si₃N₄) may be used as the inorganic insulating layer 14.

Any of polyimide (PI), benzocyclobutane (BCB), or poly p-phenylenebenzobisoxazole (PBO) may be used as the organic insulating layer 15.

In the first embodiment, the bump electrode 10b made of the solder material having the melting point of 210° C. to 220° C. is provided at a leading end portion of the columnar electrode 10el.

For example, lead (Pb)-free binary solder is used as the bump electrode 10b. That is, any of tin (Sn)-copper (Cu) solder, tin (Sn)-silver (Ag) solder or tin (Sn)-zinc (Zn) solder may be used as the bump electrode 10b.

Lead (Pb)-free ternary solder may be used as the bump electrode 10b. For example, any of tin (Sn)-silver (Ag)-copper (Cu) solder, tin (Sn)-silver (Ag)-indium (In) solder, or tin (Sn)-zinc (Zn)-bismuth (Bi) solder may be used as the bump electrode 10b.

Lead (Pb)-free quarternary solder may be used as the bump electrode 10b. For example, any of tin (Sn)-silver (Ag)-copper (Cu)-bismuth (Bi) solder or tin (Sn)-silver (Ag)-indium (In)-bismuth (Bi) solder may be used as the bump electrode 10b.

In the first embodiment, a solder paste adheres to the surface of the bump electrode 10b in the semiconductor element 10.

As illustrated in FIG. 2B, at least part of the bump electrode 10b in the semiconductor element 10 is brought into contact with a solder paste 30. Using a squeeze, the solder paste 30 is evenly applied onto a support board 50 having a flat surface.

At this point, the semiconductor element 10 is sucked and retained by a bonding tool (not illustrated), the semiconductor element 10 descends onto the support board 50, and the bump electrode 10b is dipped in the solder paste 30, thereby causing the solder paste 30 to adhere to the surface of the bump electrode 10b.

The solder paste 30 is a pasty solder material in which solder particles having particle sizes of 10 μm or less are kneaded in a flux material.

Any of the tin (Sn)-bismuth (Bi) solder of the lead (Pb)-free binary solder and the tin (Sn)-bismuth (Bi)-silver (Ag) solder of the lead (Pb)-free ternary solder may be used as the solder particle. The solder particle has the melting point of 130° C. to 150° C.

Accordingly, as illustrated in FIG. 2C, the solder paste 30 containing the solder whose melting point is lower than that of the bump electrode 10b itself adheres to at least part of the surface of the bump electrode 10b brought into contact with the solder paste 30.

That is, the solder paste 30 applied to the surface of the support board 50 is transferred to the leading end portion of the bump electrode 10b of the semiconductor element 10.

In FIG. 2C, it is assumed that d1 is a thickness of the bump electrode 10b and d3 is a thickness of the solder paste 30.

As to the method of causing the solder paste 30 to adhere to the surface of the bump electrode 10b, a method of directly applying the solder paste 30 to the surface of the bump electrode 10b may be adopted instead of the transfer method.

A process for mounting the semiconductor element 10, in which the solder paste 30 adheres to the surface of the bump electrode 10b, on the circuit board 20 by the so-called flip-chip connection method will be described below.

FIG. 2D illustrates the state in which the semiconductor element 10 is placed in the so-called flip-chip manner on the circuit board 20.

The circuit board 20 is also called a support board, a wiring board, an interposer, or a package board.

An insulating base 21 made of organic insulating resin such as glass-epoxy resin, glass-Bismaleimide-Triazine (BT) resin, or polyimide may be used as the circuit board 20, and a wiring layer including a conductive member mainly containing copper (Cu) is formed in the insulating base 21 and/or the principal surface of the insulating base 21. The wiring layer may be formed in a single-sided wiring structure, a both-sided wiring structure, or a multi-layer wiring structure as need arises.

Plural electrode pads 20p are provided in one (upper surface) of the principal surfaces of the circuit board 20. The electrode pad 20p corresponding to at least the electrode of the semiconductor element 10 is connected to the wiring layer.

A circumferential edge portion of the upper surface of the electrode pad 20p and an exposed surface of the insulating base 21 are coated with a solder resist 22, and a tinning (tinning layer) 20b is provided so as to extend on the solder resist 22 from a surface region of the electrode pad 20p that is not coated with the solder resist 22.

In the configuration, for example, a metal mainly containing copper (Cu) is used as the electrode pad 20p, and a two-layer plating layer (not illustrated) is provided in the surface of the electrode pad 20p in order to suppress the diffusion reaction of the solder material as need arises. In the two-layer plating layer, nickel (Ni) and gold (Au) are sequentially deposited from the lower layer.

A planar shape of the electrode pad 20p may be a circular shape having a diameter of 50 μm to 150 μm, and the electrode pads 20p may be provided at intervals of 100 μm to 250 μm.

A solder material having a melting point of 210° C. to 220° C. may be used as the tinning 20b provided on the electrode pad 20p.

For example, lead (Pb)-free binary solder may be used as the tinning 20b. That is, any of the tin (Sn)-copper (Cu) solder, the tin (Sn)-silver (Ag) solder, and the tin (Sn)-zinc (Zn) solder may be used as the tinning 20b.

The lead (Pb)-free ternary solder may be used as the tinning 20b. For example, any of the tin (Sn)-silver (Ag)-copper (Cu) solder, the tin (Sn)-silver (Ag)-indium (In) solder, and the tin (Sn)-zinc (Zn)-bismuth (Bi) solder may be used as the tinning 20b.

The lead (Pb)-free quarternary solder may be used as the tinning 20b. For example, any of the tin (Sn)-silver (Ag)-copper (Cu)-bismuth (Bi) solder and the tin (Sn)-silver (Ag)-indium (In)-bismuth (Bi) solder may be used as the tinning 20b.

In the structure of FIG. 2D, the semiconductor element 10 is placed on the circuit board 20 while the solder paste 30 coated with the bump electrode 10b in the semiconductor element 10 is in contact with the tinning 20b coated with the electrode pad 20p of the circuit board 20.

In the configuration, a thermal expansion coefficient ranges from 3 ppm/° C. to 4 ppm/° C. in a direction parallel to the principal surface of the semiconductor substrate 11 of the semiconductor element 10, and a thermal expansion coefficient ranges from 10 ppm/° C. to 17 ppm/° C. in a direction parallel to the principal surface of the insulating base 21 of the circuit board 20.

In FIG. 2D, it is assumed that d2 is a thickness of the tinning 20b.

While the semiconductor element 10 is placed on the circuit board 20, the semiconductor element 10 is heated by a heating unit provided in a support table (not illustrated) that supports the circuit board 20, thereby performing a reflow treatment of solder particles included in the solder paste 30.

At this point, a heating treatment temperature in the reflow treatment is set to a temperature at which only the solder particles included in the solder paste 30 are melted.

That is, the heating treatment temperature is set to a temperature that is equal to or more than the melting points of the solder particles included in the solder paste 30 and is lower than the melting points of the bump electrode 10b and tinning 20b, and, for example, the heating treatment temperature is set to 150° C. to 170° C. For example, a time necessary for the reflow treatment is set to 30 seconds to 3 minutes.

As illustrated in FIG. 2E, the semiconductor element 10 is expanded in directions of an arrow a and an arrow a′ parallel to the principal surface of the semiconductor substrate 11 by the heating in the solder reflow treatment. The arrow a and the arrow a′ are opposite to each other.

On the other hand, the circuit board 20 is expanded in directions of an arrow b and an arrow b′ parallel to the principal surface of the insulating base 21. The arrow b and the arrow b′ are opposite to each other.

At this point, the semiconductor element 10 differs from the circuit board 20 in the expanded amount based on the difference in thermal expansion coefficient. In FIG. 2E, the difference in expanded amount is expressed by length of the arrow.

That is, the circuit board 20 is expanded larger than the semiconductor element 10 in the direction parallel to the principal surface of the semiconductor element 10.

However, the heating temperature at that time is lower than the melting points of the bump electrode 10b and tinning 20b, and large stress concentration is not generated to the semiconductor element 10.

The solder particles included in the solder paste 30, the bump electrode 10b, and the tinning 20b diffuse mutually by sustaining the solder reflow treatment, so that the solder particles, the bump electrode 10b, and the tinning 20b are integrated as a bump 40 as illustrated in FIG. 2F.

Therefore, the electrode 10el of the semiconductor element 10 and the electrode pad 20p of the circuit board 20 are mechanically connected through the bump 40, and the semiconductor element 10 is flip-chip mounted on the circuit board 20.

That is, the semiconductor element 10 and the circuit board 20 may be electrically connected.

In a process for cooling the semiconductor element 10 to a room temperature (for example, 25° C.) after the solder reflow treatment, the semiconductor element 10 is contracted in directions of an arrow c and an arrow c′ parallel to the principal surface of the semiconductor substrate 11. The arrow c and the arrow c′ are opposite to each other.

The circuit board 20 is contracted in directions of an arrow d and an arrow d′ parallel to the principal surface of the insulating base 21. The arrow d and the arrow d′ are opposite to each other.

At this point, the semiconductor element 10 differs from the circuit board 20 in the contracted amount based on the difference in thermal expansion coefficient. In FIG. 2F, the difference in contracted amount is expressed by length of the arrow.

That is, the circuit board 20 is contracted larger than the semiconductor element 10 in the direction parallel to the principal surface of the semiconductor element 10.

However, the temperature is changed at that time from the melting temperature of the solder particles included in the solder paste 30 to room temperature, and the large stress concentration is not generated to the semiconductor element 10.

In the producing method of the first embodiment, using the connecting member made of the low-melting-point solder material, the heating temperature may be lowered in the solder reflow treatment in the process for flip-chip mounting the semiconductor element 10 on the circuit board 20, so that an amount of stress applied to the semiconductor element 10 may be reduced.

Therefore, the stress concentration to the low-dielectric insulating layer 12 may be reduced in the semiconductor element 10, and the breakage or peel-off of the low-dielectric insulating layer 12 may be prevented.

In the first embodiment, assuming that d1 is the thickness of the bump electrode 10b, d3 is the thickness of the solder paste 30, and d2 is the thickness of the tinning 20b, preferably a ratio of (d1+d2) and d3 ranges from 5:1 to 3:1.

When d3 is lower than ⅕ of (d1+d2), the evenness of the thickness d3 of the solder paste 30 is easy to lower.

On the other hand, when d3 is more than ⅓ of (d1+d2), the melting point of the integrated bump 40 is easily converted into the melting point (130° C. to 150° C.) of the solder component in the solder paste 30, and the melting point of the bump 40 becomes lower than the melting points of the bump electrode 10b and tinning 20b, which causes a problem in that a heat resistance property is lowered as the bump 40.

The reflow treatment may be performed with a dedicated reflow apparatus.

After the semiconductor element 10 is flip-chip mounted on the circuit board 20, a gap between the semiconductor element 10 and the circuit board 20 is filled with a sealing resin called an underfill material (not illustrated).

Alternatively, the semiconductor element 10 is coated to perform a resin sealing treatment (not illustrated).

A solder ball (not illustrated) constituting an external connection terminal is provided in the other principal surface (backside) of the circuit board 20 to form a semiconductor device having a BGA (Ball Grid Array) structure.

In cases where the large circuit board is used to mount plural semiconductor elements on the circuit board, the resin sealing treatment is collectively performed to the plural semiconductor elements, and the external connection terminal is provided. Then, the wiring board and the sealing resin that is provided on the wiring board to cover the semiconductor element therewith are cut in a thickness direction to form pieces of semiconductor devices.

In the first embodiment, when the semiconductor element 10 in which the bump electrode 10b is provided in the principal surface is mounted on the circuit board 20 by the flip-chip bonding method, the tinning 20b is provided on the electrode pad 20p of the circuit board 20, at least part of the surface of the bump electrode 10b is coated with the solder paste 30 containing the solder particles whose melting points are lower than the melting points of the bump electrode 10b and tinning 20b, and the semiconductor element 10 is placed on the circuit board 20 while the bump electrode 10b and the tinning 20b are caused to face each other with the solder paste 30 interposed therebetween.

Then the solder particles in the solder paste 30 are melted to integrate the bump electrode 10b, the solder particles, and the tinning 20b.

Therefore, the electrode of the semiconductor element 10 and the electrode pad of the circuit board 20 are mechanically connected through the bump 40, and the semiconductor element 10 is flip-chip mounted on the circuit board 20.

In the semiconductor device producing method of the first embodiment, only the solder particles of the solder paste 30 having the relatively low melting point are melted in the lead (Pb)-free solder, and the high-melting-point solder (bump electrode 10b and tinning 20b) may easily be integrated.

The connecting member including the low-melting-point solder is interposed between the pieces of high-melting-point solder, and the reflow treatment is performed near the melting point of the low-melting-point solder, so that the reflow treatment temperature may be lowered compared with the case in which the pieces of high-melting-point solder are directly melted and joined.

Accordingly, when the semiconductor element 10 and the circuit board 20 are heated to the reflow treatment temperature, and when the semiconductor element 10 and the circuit board 20 are cooled from the reflow treatment temperature to room temperature, the temperature changes of the semiconductor element 10 and the circuit board 20 become smaller compared with the case in which the pieces of high-melting-point solder are directly melted and joined.

A strong stress is not applied to the semiconductor element 10, thereby preventing the stress concentration to the insulating layer formed in the principal surface of the semiconductor element 10.

Even if the low-dielectric insulating layer is used as the insulating layer, the breakage or peel-off of the low-dielectric insulating layer is avoided, and the short circuit or disconnection of the wiring layer and inter-layer connection portion that are provided in the low-dielectric insulating layer is prevented.

The bump electrode 10b, the granular solder included in the solder paste 30, and the tinning 20b diffuse mutually during the reflow treatment to form the bump 40 having even composition.

Therefore, the melting point of the bump 40 becomes a value between the melting point of the high-melting-point bump electrode 10b and the melting point of the granular solder included in the solder paste 30. That is, the melting point of the bump 40 becomes higher than the melting point of the granular solder included in the solder paste 30 because of the presence of the high-melting-point bump electrode 10b. Accordingly, even if the bump 40 is exposed to a high temperature in operating the semiconductor device, the bump 40 is not melted, and high reliability may be maintained.

Thus, in the first embodiment, the high-reliability semiconductor device may be produced with a high production yield at low cost.

A circuit board mainly containing an inorganic insulating material such as glass may be used as the circuit board 20. However, the circuit board mainly containing the inorganic insulating material is more expensive than the circuit board mainly containing the organic insulating material, and the production cost of the semiconductor device is possibly increased when the circuit board mainly containing the inorganic insulating material is used.

### Second Embodiment

A semiconductor producing method according to a second embodiment of the invention will be described below.

In the second embodiment, a part corresponding to the part of the first embodiment is designated by the same numeral, and the description is not repeated here.

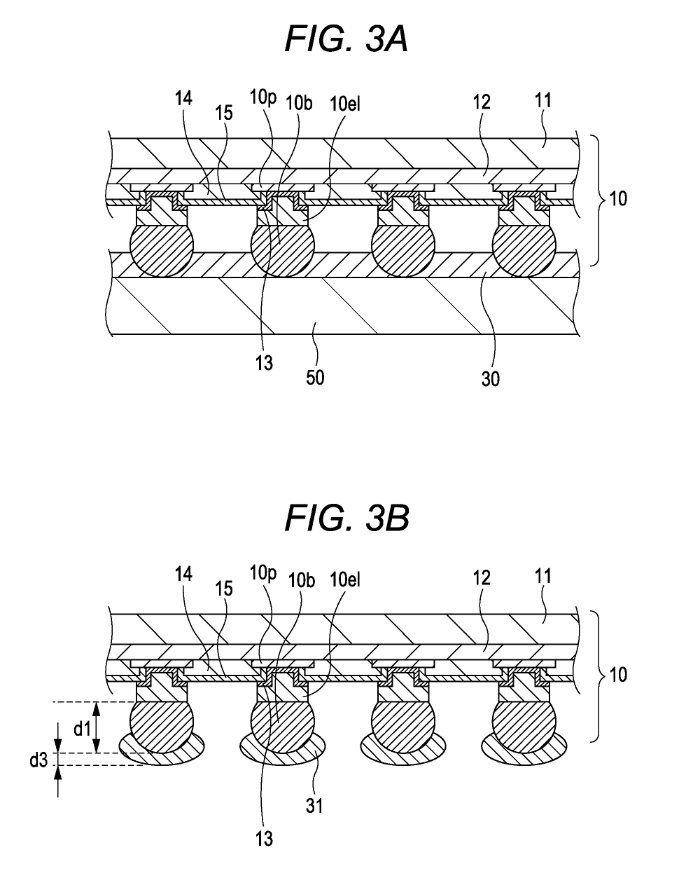

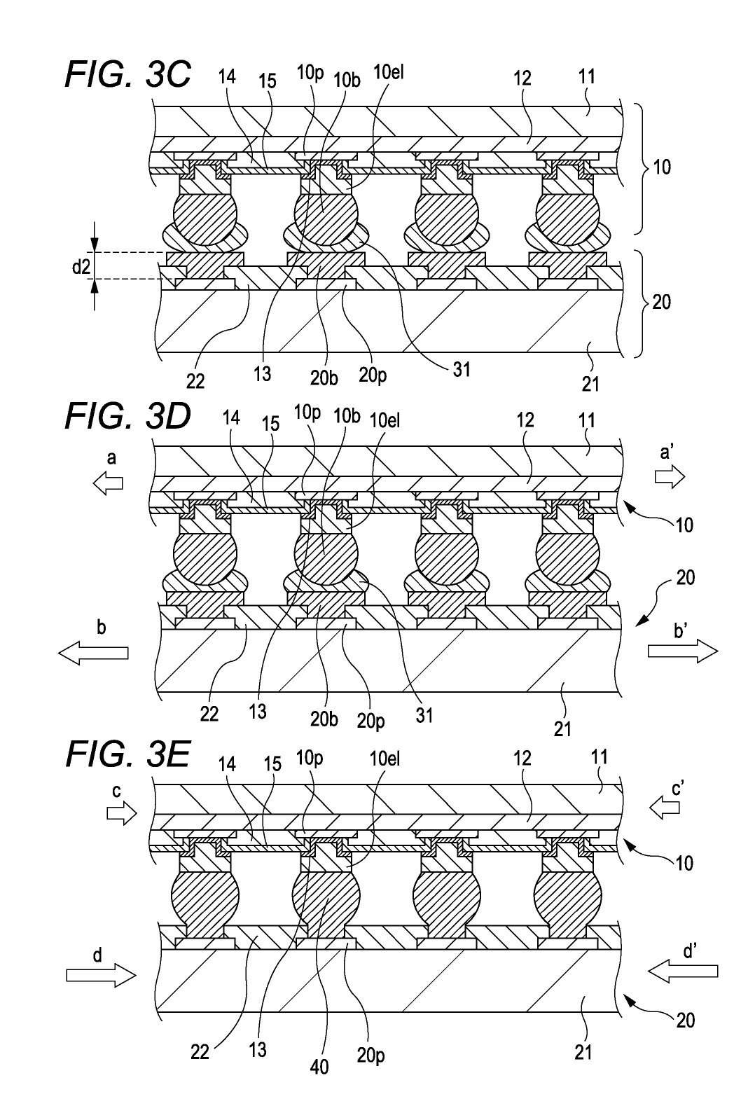

A semiconductor device producing method of the second embodiment of the invention will be described with reference to FIGS. 3A-3E. In the second embodiment, the solder member that is of the connecting member adheres to the surface of the bump electrode 10b of the semiconductor element 10.

As illustrated in FIG. 3A, at least part of the bump electrode 10b in the semiconductor element 10 is brought into contact with the solder paste 30. Using the squeeze 51, the solder paste 30 is evenly applied onto the support board 50 having a flat surface.

At this point, the semiconductor element 10 is sucked and retained by the bonding tool (not illustrated), the semiconductor element 10 descends onto the support board 50, and the bump electrode 10b of the semiconductor element 10 is dipped in the solder paste 30.

The solder paste 30 is a pasty solder material in which solder particles having particle sizes of 40 μm or less are kneaded in a flux material.

Any of the tin (Sn)-bismuth (Bi) solder of the lead (Pb)-free binary and the tin (Sn)-bismuth (Bi)-silver (Ag) solder of the lead (Pb)-free ternary solder may be used as the solder particle. The solder particle may have a melting point of 130° C. to 150° C.

While the state in which the bump electrode 10b of the semiconductor element 10 is dipped in the solder paste 30 is maintained, the bump electrode 10b is heated to a temperature that is equal to and more than the melting point of the solder particle and lower than the melting point of the bump electrode 10b using the heating unit of the bonding tool.

Only the solder particles of the solder paste 30 are melted near the bump electrode 10b by the heating treatment, and the melted solder component adheres to at least part of the surface of the bump electrode 10b.

Then, when the semiconductor element 10 is cooled to room temperature, because the solder component is also cooled below the melting point thereof, a solder member 31 containing the solder component adheres to part of the surface of the bump electrode 10b.

That is, at least part of the surface of the bump electrode 10b is coated with the solder member 31 that is of the connecting member.

FIG. 3B illustrates the state in which at least part of the surface of the bump electrode 10b is coated with the solder member 31.

In FIG. 3B, it is assumed that d1 is the thickness of the bump electrode 10b and d3 is the thickness of the solder member 31.

A process for mounting the semiconductor element 10, in which the solder paste 30 adheres to the surface of the bump electrode 10b, on the circuit board 20 by the so-called flip-chip connection method will be described below.

FIG. 3C illustrates the state in which the semiconductor element 10 is placed in the so-called flip-chip manner on the circuit board 20.

The circuit board 20 is also called a support board, a wiring board, an interposer, or a package board.

The insulating base 21 made of organic insulating resin such as glass-epoxy resin, glass-Bismaleimide-Triazine (BT) resin, or polyimide may be used as the circuit board 20, and the wiring layer including the conductive member mainly containing copper (Cu) is formed in the insulating base 21 and/or the principal surface of the insulating base 21. The wiring layer may be formed in a single-sided wiring structure, a both-sided wiring structure, or a multi-layer wiring structure as need arises.

The plural electrode pads 20p are provided in one (upper surface) of the principal surfaces of the circuit board 20. The electrode pad 20p corresponding to at least the electrode of the semiconductor element 10 is connected to the wiring layer.

The circumferential edge portion of the upper surface of the electrode pad 20p and the exposed surface of the insulating base 21 are coated with the solder resist 22, and the tinning 20b is provided while extended on the solder resist 22 from the surface region that is not coated with the solder resist 22 of the electrode pad 20p. The tinning 20b may be made of a solder material having a melting point of 210° C. to 220° C.

In the configuration of FIG. 3C, the semiconductor element 10 is placed while the solder member 31 coated with the bump electrode 10b of the semiconductor element 10 is in contact with the tinning 20b coated with the electrode pad 20p on the circuit board 20.

In the configuration, the thermal expansion coefficient ranges from 3 ppm/° C. to 4 ppm/° C. in the direction parallel to the principal surface of the semiconductor substrate 11 of the semiconductor element 10, and the thermal expansion coefficient ranges from 10 ppm/° C. to 17 ppm/° C. in the direction parallel to the principal surface of the insulating base 21 of the circuit board 20.

In FIG. 3C, it is assumed that d2 is the thickness of the tinning 20b.

While the semiconductor element 10 is placed on the circuit board 20, the semiconductor element 10 is heated by the heating unit provided in the support table (not illustrated) that supports the circuit board 20, thereby performing the reflow treatment of the solder member 31.

At this point, the heating treatment temperature in the solder reflow treatment is set to a temperature at which only the solder member 31 is melted.

That is, the heating treatment temperature is set to a temperature that is equal to or more than the melting point of the solder member 31 and is lower than the melting points of the bump electrode 10b and tinning 20b, and, for example, the heating treatment temperature is set to 150° C. to 170° C. The time necessary for the reflow treatment is, for example, set to 30 seconds to 3 minutes.

As illustrated in FIG. 3D, the semiconductor element 10 is expanded in the directions of the arrows a and a′ parallel to the principal surface of the semiconductor substrate 11 by the heating in the solder reflow treatment. The arrow a and the arrow a′ are opposite to each other.

On the other hand, the circuit board 20 is expanded in the directions of the arrows b and b′ parallel to the principal surface of the insulating base 21. The arrow b and the arrow b′ are opposite to each other.

At this point, the semiconductor element 10 differs from the circuit board 20 in the expanded amount based on the difference in thermal expansion coefficient. In FIG. 3D, the difference in expanded amount is expressed by length of the arrow.

That is, the circuit board 20 is expanded larger than the semiconductor element 10 in the direction parallel to the principal surface of the semiconductor element 10.

However, the heating temperature at that time is lower than the melting points of the bump electrode 10b and tinning 20b, and the large stress concentration is not generated to the semiconductor element 10.

The solder member 31, the bump electrode 10b, and the tinning 20b diffuse mutually by sustaining the solder reflow treatment, so that the solder member 31, the bump electrode 10b, and the tinning 20b are integrated as the bump 40 as illustrated in FIG. 3E.

Therefore, the electrode 10el of the semiconductor element 10 and the electrode pad 20p of the circuit board 20 are mechanically connected through the bump 40, and the semiconductor element 10 is flip-chip mounted on the circuit board 20.

That is, the semiconductor element 10 and the circuit board 20 may be electrically connected.

In the process for cooling the semiconductor element 10 to room temperature (for example, 25° C.) after the solder reflow treatment, the semiconductor element 10 is contracted in the directions of the arrows c and c′ parallel to the principal surface of the semiconductor substrate 11. The arrow c and the arrow c′ are opposite to each other.

The circuit board 20 is contracted in the directions of the arrows d and d′ parallel to the principal surface of the insulating base 21. The arrow d and the arrow d′ are opposite to each other.

At this point, the semiconductor element 10 differs from the circuit board 20 in the contracted amount based on the difference in thermal expansion coefficient. In FIG. 3E, the difference in contracted amount is expressed by length of the arrow.

That is, the circuit board 20 is contracted larger than the semiconductor element 10 in the direction parallel to the principal surface of the semiconductor element 10.

However, the temperature is changed at that time from the melting temperature of the solder member 31 to room temperature, and large stress concentration is not generated to the semiconductor element 10.

In the producing method of the second embodiment, the heating temperature may be lowered in the solder reflow treatment in the process for flip-chip mounting the semiconductor element 10 on the circuit board 20, and therefore the amount of stress applied to the semiconductor element 10 may be reduced.

Therefore, the stress concentration to the low-dielectric insulating layer 12 may be reduced and suppressed in the semiconductor element 10, and the breakage or peel-off of the low-dielectric insulating layer 12 may be prevented.

In the second embodiment, assuming that d1 is the thickness of the bump electrode 10b, d3 is the thickness of the solder member 31, and d2 is the thickness of the tinning 20b, preferably the ratio of (d1+d2) and d3 ranges from 5:1 to 3:1.

That is, when d3 is lower than ⅕ of (d1+d2), the evenness of the thickness d3 of the solder member 31 is easy to lower.

On the other hand, when d3 is more than ⅓ of (d1+d2), the melting point of the integrated bump 40 is easily converted into the melting point (130° C. to 150° C.) of the solder component of the solder member 31, and the melting point of the bump 40 becomes lower than the melting points of the bump electrode 10b and tinning 20b, which causes the problem in that a heat resistance property of the bump 40 is lowered.

The reflow treatment may be performed with a dedicated reflow apparatus.

After the semiconductor element 10 is flip-chip mounted on the circuit board 20, the gap between the semiconductor element 10 and the circuit board 20 may be filled with the sealing resin called an underfill material (not illustrated).

Alternatively, the semiconductor element 10 may be coated by a resin sealing treatment.

The solder ball (not illustrated) constituting the external connection terminal is provided in the other principal surface (backside) of the circuit board 20 to form the semiconductor device having the BGA (Ball Grid Array) structure.

In cases where a large circuit board is used to mount plural semiconductor elements on the circuit board, the resin sealing treatment is collectively performed to the plural semiconductor elements, and the external connection terminal is provided. Then, the wiring board and the sealing resin that is provided on the wiring board to cover the semiconductor element therewith are cut in a thickness direction to form the pieces of semiconductor devices.

In the second embodiment, when the semiconductor element 10 in which the bump electrode 10b is provided in the principal surface is mounted on the circuit board 20 by the flip-chip bonding method, the tinning 20b is provided on the electrode pad 20p of the circuit board 20, at least part of the surface of the bump electrode 10b is coated with the solder member 31 whose melting point is lower than the melting points of the bump electrode 10b and tinning 20b, and the semiconductor element 10 is placed on the circuit board 20 while the bump electrode 10b and the tinning 20b are caused to face each other with the solder member 31 interposed therebetween.

Then the solder member 31 is melted to integrate the bump electrode 10b, the solder member 31, and the tinning 20b. Therefore, the electrode of the semiconductor element 10 and the electrode pad of the circuit board 20 are mechanically connected through the bump 40, and the semiconductor element 10 is flip-chip mounted on the circuit board 20.

In the semiconductor device producing method of the second embodiment, the connecting member including the low-melting-point solder member 31 is interposed between the pieces of high-melting-point solder, and the reflow treatment is performed near the melting point of the solder member 31, so that the reflow treatment temperature may be lowered compared with the case in which the pieces of high-melting-point solder are directly melted and joined.

When the semiconductor element 10 and the circuit board 20 are heated to the reflow treatment temperature, and when the semiconductor element 10 and the circuit board 20 are cooled from the reflow treatment temperature to room temperature, the temperature changes of the semiconductor element 10 and the circuit board 20 become smaller compared with the case in which the pieces of high-melting-point solder are directly melted and joined.

A strong stress is not applied to the semiconductor element 10, thereby preventing the stress concentration to the insulating layer formed in the principal surface of the semiconductor element 10.

Therefore, even if the low-dielectric insulating layer is used as the insulating layer, the breakage or peel-off of the low-dielectric insulating layer is avoided, and short circuit or disconnection of the wiring layer and inter-layer connection portion that are provided in the low-dielectric insulating layer is prevented.

Thus, in the second embodiment, the high-reliability semiconductor device may be produced with a high production yield.

Further, in the second embodiment, the solder particles of the solder paste 30 are put in the melted state, and the solder component in the melted state is caused to adhere as the solder member 31 to the surface of the bump electrode 10b.

That is, the low-melting-point solder component is formed as the solder member 31 in the surface of the bump electrode 10b irrespective of viscosity of the solder paste 30.

Accordingly, even if the particle diameter fluctuates in the solder particles included in the solder paste 30, the low-melting-point solder component may adhere securely to the surface of the bump electrode 10b.

The solder paste having fluctuation in solder particle diameter is inexpensive compared with the solder paste having the even solder particle diameter, so that the production cost may be reduced in the semiconductor device producing method of the second embodiment.

### Third Embodiment

A semiconductor producing method according to a third embodiment of the invention will be described below.

In the third embodiment, a part corresponding to the parts of the first and second embodiments is designated by the same numeral, and the description is not repeated here.

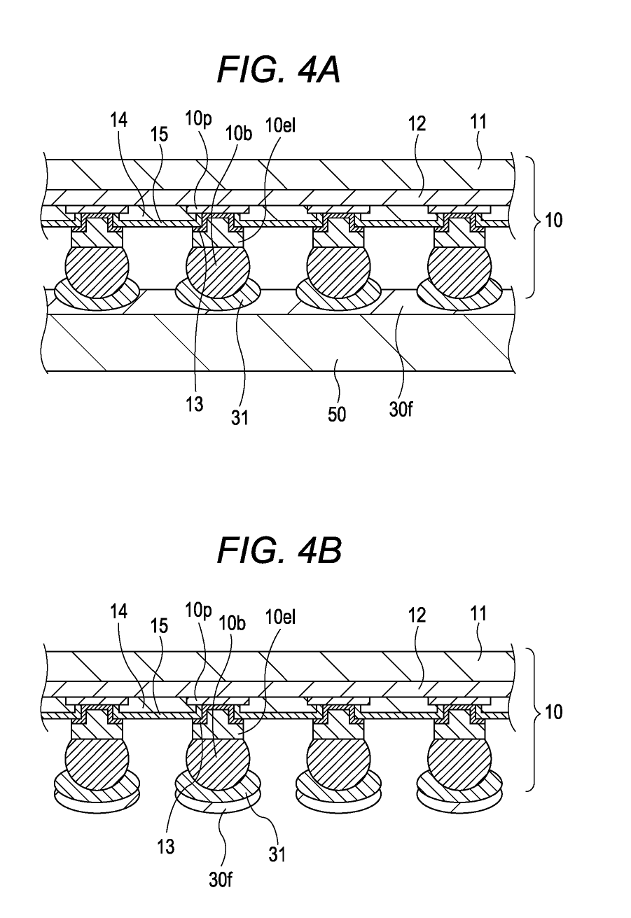

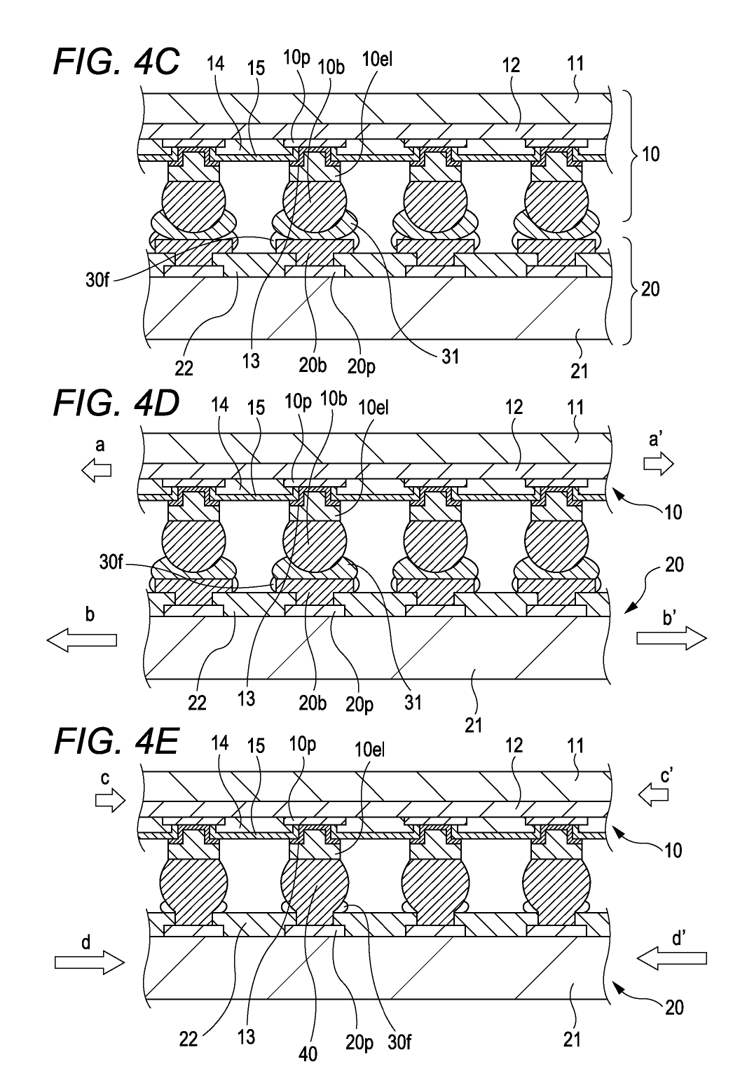

FIGS. 4A-4E are sectional schematic diagrams of a main part explaining a semiconductor device producing method of the third embodiment.

In the third embodiment, the solder member that is of the connecting member and the flux material adhere to the surface of the bump electrode 10b of the semiconductor element 10 while overlapping each other.

In the third embodiment, first the semiconductor element 10 in which a solder member 31 adheres to at least part of the surface of the bump electrode 10b is prepared.

The processes of FIGS. 3A and 3B in the second embodiment are applied to the semiconductor element 10.

In the semiconductor element 10 in which the solder member 31 adheres to at least part of the surface of the bump electrode 10b, the solder member 31 is brought into contact with the flux material 30f disposed on the support board 50 having the flat surface. FIG. 4A illustrates the state in which the solder member 31 is brought into contact with the flux material 30f.

At this point, the semiconductor element 10 is sucked and retained by the bonding tool (not illustrated), the semiconductor element 10 descend onto the support board 50, and the solder member 31 adhering to the bump electrode 10b of the semiconductor element 10 is dipped in a flux material 30f.

Then, the semiconductor element 10 is separated from the support board 50, whereby the flux material 30f is transferred to the surface of the solder member 31. FIG. 4B illustrates the state in which the flux material 30f is transferred to the surface of the solder member 31.

As to the method of causing the flux material 30f to adhere to the surface of the solder member 31, a method of directly applying the flux material to the surface of the solder member 31 may be adopted instead of the dipping method. A process for mounting the semiconductor element 10, in which the solder member 31 is provided in the surface of the bump electrode 10b and the solder member 31 is coated with the flux material 30f, on the circuit board 20 by the so-called flip-chip connection method will be described below.

FIG. 4C illustrates the state in which the semiconductor element 10 is placed in the so-called flip-chip manner on the circuit board 20.

The circuit board 20 is also called a support board, a wiring board, an interposer, or a package board.

The insulating base 21 made of organic insulating resin such as glass-epoxy resin, glass-Bismaleimide-Triazine (BT), or polyimide is used as the circuit board 20, and the wiring layer including the conductive member mainly containing copper (Cu) is formed in the insulating base 21 and/or the principal surface of the insulating base 21. The wiring layer may be formed in a single-sided wiring structure, a both-sided wiring structure, or a multi-layer wiring structure as need arises.

The plural electrode pads 20p are provided in one (upper surface) of the principal surfaces of the circuit board 20. The electrode pad 20p corresponding to at least the electrode of the semiconductor element 10 is connected to the wiring layer.

The circumferential edge portion of the upper surface of the electrode pad 20p and the exposed surface of the insulating base 21 are coated with the solder resist 22, and the tinning 20b is provided while extended on the solder resist 22 from the surface region that is not coated with the solder resist 22 of the electrode pad 20p. The tinning 20b may be made of a solder material having a melting point of 210° C. to 220° C.

That is, in the configuration of FIG. 4C, the semiconductor element 10 is placed while the solder member 31 coated with the bump electrode 10b in the semiconductor element 10 is in contact with the tinning 20b coated with the electrode pad 20p of the circuit board 20.

The flux material 30f is stopped at a contact boundary between the tinning 20b and the solder member 31 and the surrounding of the contact boundary.

In the configuration, the thermal expansion coefficient ranges from 3 ppm/° C. to 4 ppm/° C. in the direction parallel to the principal surface of the semiconductor substrate 11 of the semiconductor element 10, and the thermal expansion coefficient ranges from 10 ppm/° C. to 17 ppm/° C. in the direction parallel to the principal surface of the insulating base 21 of the circuit board 20.

While the semiconductor element 10 is placed on the circuit board 20, the semiconductor element 10 is heated by a heating unit (not illustrated) that supports the circuit board 20, thereby performing a reflow treatment of the solder member 31.

At this point, the heating treatment temperature in the reflow treatment is set to a temperature at which only the solder member 31 is melted.

That is, the heating treatment temperature is set to a temperature that is equal to or more than the melting point of the solder member 31 and is lower than the melting points of the bump electrode 10b and tinning 20b, and, for example, the heating treatment temperature is set to 150° C. to 170° C. The time necessary for the reflow treatment is set, for example, to 30 seconds to 3 minutes.

As illustrated in FIG. 4D, the semiconductor element 10 is expanded in the directions of the arrows a and a′ parallel to the principal surface of the semiconductor substrate 11 by the heating in the solder reflow treatment. The arrow a and the arrow a′ are opposite to each other.

On the other hand, the circuit board 20 is expanded in the directions of the arrows b and b′ parallel to the principal surface of the insulating base 21. The arrow b and the arrow b′ are opposite to each other.

At this point, the semiconductor element 10 differs from the circuit board 20 in the expanded amount based on the difference in thermal expansion coefficient. In FIG. 4D, the difference in expanded amount is expressed by length of the arrow.

That is, the circuit board 20 is expanded larger than the semiconductor element 10 in the direction parallel to the principal surface of the semiconductor element 10.

However, the heating temperature at that time is lower than the melting points of the bump electrode 10b and tinning 20b, and the large stress concentration is not generated to the semiconductor element 10.

The solder member 31, the bump electrode 10b, and the tinning 20b diffuse mutually by sustaining the solder reflow treatment, so that the solder member 31, the bump electrode 10b, and the tinning 20b are integrated as the bump 40 as illustrated in FIG. 4E.

Therefore, the electrode 10el of the semiconductor element 10 and the electrode pad 20p of the circuit board 20 are mechanically connected through the bump 40, and the semiconductor element 10 is flip-chip mounted on the circuit board 20.

That is, the semiconductor element 10 and the circuit board 20 may be electrically connected.

In the soldering, the flux material 30f remaining around the bump 40 is removed by a washing treatment as need arises.

In the process for cooling the semiconductor element 10 to room temperature (for example, 25° C.) after the solder reflow treatment, the semiconductor element 10 is contracted in the directions of the arrows c and c′ parallel to the principal surface of the semiconductor substrate 11. The arrow c and the arrow c′ are opposite to each other.

The circuit board 20 is contracted in the directions of the arrows d and d′ parallel to the principal surface of the insulating base 21. The arrow d and the arrow d′ are opposite to each other.

At this point, the semiconductor element 10 differs from the circuit board 20 in the contracted amount based on the difference in thermal expansion coefficient. In FIG. 4E, the difference in contracted amount is expressed by length of the arrow.

That is, the circuit board 20 is contracted larger than the semiconductor element 10 in the direction parallel to the principal surface of the semiconductor element 10.

However, the temperature is changed at that time from the melting temperature of the solder member 31 to the room temperature, and large stress concentration is not generated to the semiconductor element 10.

In the producing method of the third embodiment, the heating temperature is lowered in the solder reflow treatment in the process for flip-chip mounting the semiconductor element 10 on the circuit board 20, so that the amount of stress applied to the semiconductor element 10 may be reduced.

Therefore, the stress concentration to the low-dielectric insulating layer 12 may be reduced and suppressed in the semiconductor element 10, and the breakage or peel-off of the low-dielectric insulating layer 12 may be prevented.

The reflow treatment may be performed with the dedicated reflow apparatus.

After the semiconductor element 10 is flip-chip mounted on the circuit board 20, the gap between the semiconductor element 10 and the circuit board 20 may be filled with the sealing resin called the underfill material (not illustrated).

Alternatively, the semiconductor element 10 may be coated to perform the resin sealing treatment.

The solder ball constituting the external connection terminal is provided in the other principal surface (backside) of the circuit board 20 to form the semiconductor device having the BGA (Ball Grid Array) structure.

In cases where a large circuit board is used to mount plural semiconductor elements on the circuit board, the resin sealing treatment is collectively performed to the plural semiconductor elements, and the external connection terminal is provided. Then, the wiring board and the sealing resin that is provided on the wiring board to cover the semiconductor element therewith are cut in the thickness direction to form the pieces of semiconductor devices.

In the third embodiment, when the semiconductor element 10 in which the bump electrode 10b is provided in the principal surface is mounted on the circuit board 20 by the flip-chip bonding method, the tinning 20b is provided on the electrode pad 20p of the circuit board 20, at least part of the surface of the bump electrode 10b is coated with the solder member 31 and flux material 30f whose melting points are lower than the melting points of the bump electrode 10b and tinning 20b, and then, the semiconductor element 10 is placed on the circuit board 20 while the bump electrode 10b and the tinning 20b are caused to face each other with the solder member 31 and the flux material 30f interposed therebetween.

Then the solder member 31 is melted to integrate the bump electrode 10b, the solder member 31, and the tinning 20b.

Therefore, the electrode of the semiconductor element 10 and the electrode pad of the circuit board 20 are mechanically connected through the bump 40, and the semiconductor element 10 is flip-chip mounted on the circuit board 20.

In the semiconductor device producing method of the third embodiment, the solder member 31 having the relatively low melting point in the lead (Pb)-free solder may be melted to easily integrate the pieces of high-melting-point solder (bump electrode 10b and tinning 20b).

That is, the connecting member including the low-melting-point solder is interposed between the pieces of high-melting-point solder, and the reflow treatment is performed near the melting point of the low-melting-point solder, so that the reflow treatment temperature may be lowered compared with the case in which the pieces of high-melting-point solder are directly melted and joined.

Accordingly, when the semiconductor element 10 and the circuit board 20 are heated to the reflow treatment temperature, and when the semiconductor element 10 and the circuit board 20 are cooled from the reflow treatment temperature to room temperature, the temperature changes of the semiconductor element 10 and the circuit board 20 become smaller compared with the case in which the pieces of high-melting-point solder are directly melted and joined.

Accordingly, the strong stress is not applied to the semiconductor element 10, thereby preventing the stress concentration to the insulating layer formed in the principal surface of the semiconductor element 10.

Even if the low-dielectric insulating layer is used as the insulating layer, the breakage or peel-off of the low-dielectric insulating layer is avoided, and the short circuit or disconnection of the wiring layer and inter-layer connection portion that are provided in the low-dielectric insulating layer is prevented.

Thus, in the third embodiment, high-reliability semiconductor device may be produced with a high production yield.

Further, in the third embodiment, the flux material 30f is previously applied to the surface of the solder member 31. Therefore, even if an oxide film is produced in the surface of the solder member 31, the oxide film is removed during the reflow treatment. Accordingly, even if the oxide film is produced in the surface of the solder member 31, the solder member 31 and the tinning 20b may securely be integrated.

### Fourth Embodiment

A semiconductor producing method according to a fourth embodiment of the invention will be described below.

In the fourth embodiment, a part corresponding to the parts of the first to third embodiments is designated by the same numeral, and the description is not repeated here.

In the fourth embodiment, the solder member 31 used as the connecting member of the second embodiment is provided in the surface of the bump electrode 10b of the semiconductor element 10 by means that is different from that of the second embodiment.

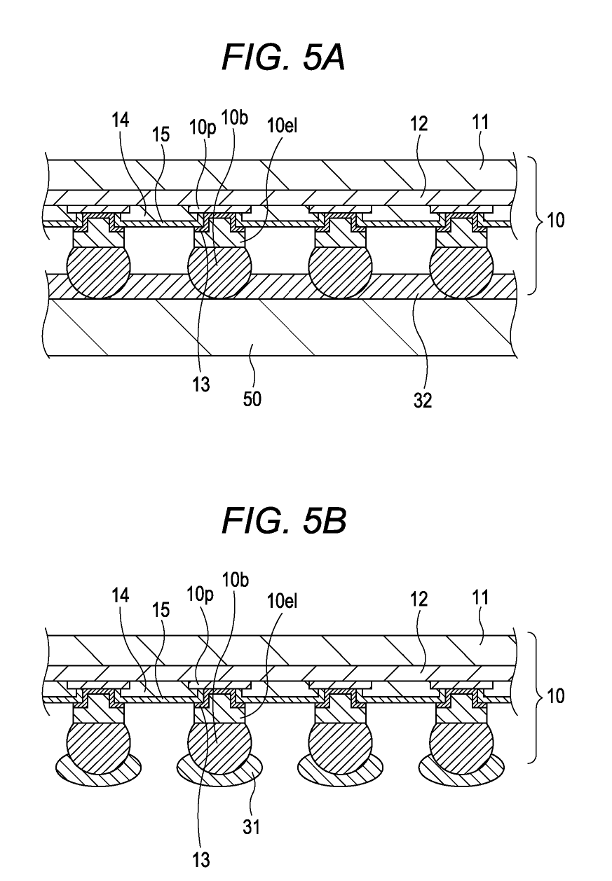

FIGS. 5A-5B are sectional schematic diagrams of a main part explaining a semiconductor device producing method of the fourth embodiment. In the fourth embodiment, the bump electrode 10b of the semiconductor element 10 is brought into contact with a solder material 32. The solder material 32 in the melting state is placed on the support board 50 having a flat surface.

FIG. 5A illustrates the state in which the bump electrode 10b is brought into contact with the solder material 32.

At this point, the semiconductor element 10 is sucked and retained by the bonding tool (not illustrated), the semiconductor element 10 descends onto the support board 50, and the bump electrode 10b of the semiconductor element 10 is dipped in the solder material 32 in the melted state.

In the solder material 32, the melted state is maintained by the heating of the heating unit (not illustrated) provided in the support board 50, and the so-called melted solder bath is formed.

The solder particle, solder piece, or solder plate is melted and used as the solder material 32. Any of the tin (Sn)-bismuth (Bi) solder of the lead (Pb)-free binary solder and the tin (Sn)-bismuth (Bi)-silver (Ag) solder of the lead (Pb)-free ternary solder is used as the solder material 32. The melting point of 130° C. to 150° C. is selected in the solder material 32.

After the dip, the semiconductor element 10 is separated from the support board 50 to transfer the solder material 32 to the surface of the bump electrode 10b, thereby obtaining the state in which the solder member 31 adheres to the surface of the bump electrode 10b.

FIG. 5B illustrates the state in which the solder member 31 adheres to the surface of the bump electrode 10b.

The semiconductor element 10, in which the solder member 31 adheres to part of the surface of the bump electrode 10b, is mounted in the flip-chip state on the circuit board 20 through the processes (see FIGS. 3C to 3E) of the second embodiment.

The effect similar to those of the first and second embodiments may be obtained in the fourth embodiment.

Further, in the fourth embodiment, the solder piece, solder plate, or solder particle is used as the solder material 32 in the melted state, that is, the solder material that forms the melted solder bath, so that the production cost may be reduced.

### Fifth Embodiment

A semiconductor producing method according to a fifth embodiment of the invention will be described below.

In the fifth embodiment, a part corresponding to the parts of the first to fourth embodiments is designated by the same numeral, and the description is not repeated here.

In the fifth embodiment, the flux material 30f used in the second embodiment is caused to adhere to the surface of the bump electrode 10b of the semiconductor element 10 by means that is different from that of the second embodiment.

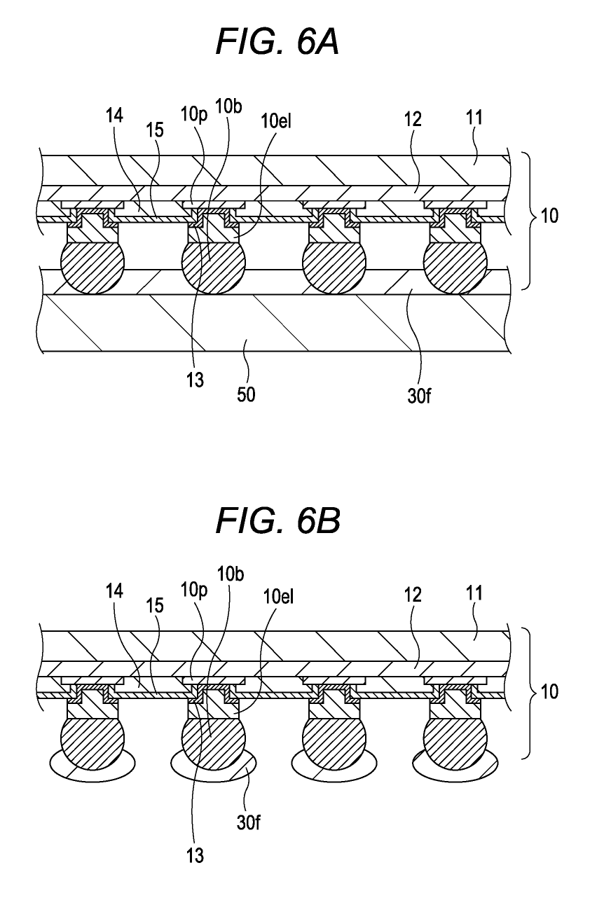

FIGS. 6A-6B are sectional schematic diagrams of a main part explaining a semiconductor device producing method of the fifth embodiment.

The solder member 31 of the semiconductor element 10 is brought into contact with the flux material 30f. The flux material 30f is disposed on the support board 50 having a flat surface. FIG. 6A illustrates the state in which the solder member 31 is brought into contact with the flux material 30f.

At this point, the semiconductor element 10 is sucked and retained by the bonding tool (not illustrated), the semiconductor element 10 descends onto the support board 50, and the bump electrode 10b of the semiconductor element 10 is dipped in the flux material 30f.

The flux material 30f is transferred to part of the surface of the bump electrode 10b by separating the semiconductor element 10 from the support board 50. FIG. 6B illustrates the state in which the flux material 30f is transferred to part of the surface of the bump electrode 10b.

Then, through the means of the fourth embodiment, the bump electrode 10b of the semiconductor element 10 is brought into contact with the solder material 32 in the melted state. The solder material 32 is disposed on the support board 50 having the flat surface.

As a result, the solder member 31 that is of the connecting member adheres to part of the surface of the bump electrode 10b (see FIG. 5B of the fourth embodiment).

The semiconductor element 10, in which the solder member 31 adheres to part of the surface of the bump electrode 10b, is mounted in the flip-chip state on the circuit board 20 through the processes (see FIGS. 3C to 3E) of the second embodiment.

The effect similar to those of the first, second, and fourth embodiments may be obtained in the fifth embodiment.

Further, in the fifth embodiment, because the flux material 30f adheres previously to the surface of the bump electrode 10b, even if the oxide film is produced in the surface of the bump electrode 10b, the oxide film is removed in dipping the bump electrode 10b in the solder material 32.

Accordingly, even if the oxide film is produced in the surface of the bump electrode 10b, the solder member 31 may adhere securely to the bump electrode 10b.

### Sixth Embodiment

A semiconductor producing method according to a sixth embodiment of the invention will be described below.

In the sixth embodiment, a part corresponding to the parts of the first to fifth embodiments is designated by the same numeral, and the description is not repeated here.

In the sixth embodiment, the flux material 30f used in the second embodiment is caused to adhere to the surface of the bump electrode 10b of the semiconductor element 10 before and after the solder member 31 adheres to the surface of the bump electrode 10b.

That is, the third to fifth embodiments are combined in the sixth embodiment.

In the sixth embodiment, first, the bump electrode 10b of the semiconductor element 10 is brought into contact with the flux material 30f. The flux material 30f is disposed on the support board 50 having the flat surface.

At this point, the semiconductor element 10 is sucked and retained by a bonding tool (not illustrated), the semiconductor element 10 descends onto the support board 50, and the bump electrode 10b of the semiconductor element 10 is dipped in the flux material 30f.

The flux material 30f is transferred to part of the surface of the bump electrode 10b by separating the semiconductor element 10 from the support board 50.

Then the bump electrode 10b of the semiconductor element 10 is brought into contact with the solder material 32 in the melted state. The solder material 32 is disposed on the support board 50 having the flat surface.

As a result, the solder member 31 that is of the connecting member adheres to part of the surface of the bump electrode 10b.

Then the bump electrode 10b of the semiconductor element 10 is brought into contact with the flux material 30f disposed on the support board 50 having the flat surface.

The semiconductor element 10 is separated from the support board 50 to transfer the flux material 30f to part of the surface of the solder member 31

Through the processes, the solder member 31 adheres to the surface of the bump electrode 10b, and the semiconductor element 10 in which the flux material 30f is transferred to the surface of the solder member 31 is placed in the so-called flip-chip manner on the circuit board 20.

Then the solder reflow treatment is performed to integrate the bump electrode 10b, the solder member 31, and the tinning 20b.

Therefore, the semiconductor device may be produced.

In the sixth embodiment, the effect similar to those of the first to fifth embodiments is obtained.

### Seventh Embodiment

A semiconductor producing method according to a seventh embodiment of the invention will be described below.

In the seventh embodiment, a part corresponding to the parts of the first to sixth embodiments is designated by the same numeral, and the description is not repeated here.

In the first to sixth embodiments, the solder material having the melting point of 130° C. to 150° C. adheres to the surface of the bump electrode 10b of the semiconductor element 10. Alternatively, the solder material may adhere to the tinning 20b provided on the electrode pad 20p in the circuit board 20.

In the seventh embodiment, the solder material having the melting point of 130° C. to 150° C. adheres as the connecting member onto the tinning 20b (melting point 210° C. to 220° C.) provided on the electrode pad 20p in the circuit board 20.

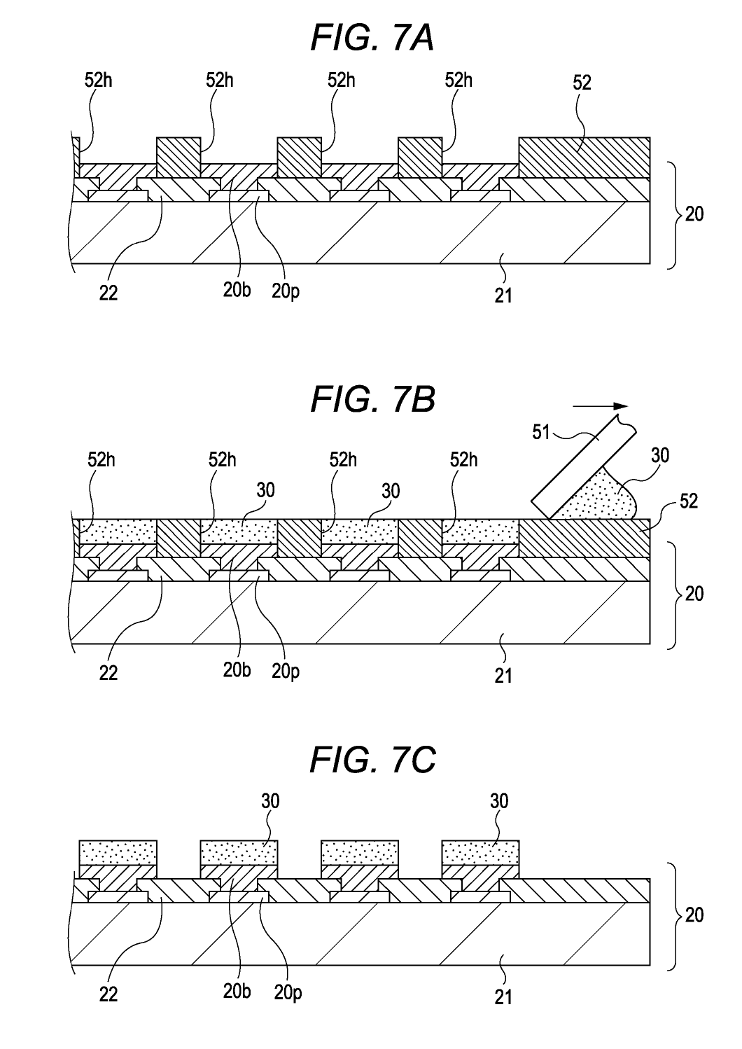

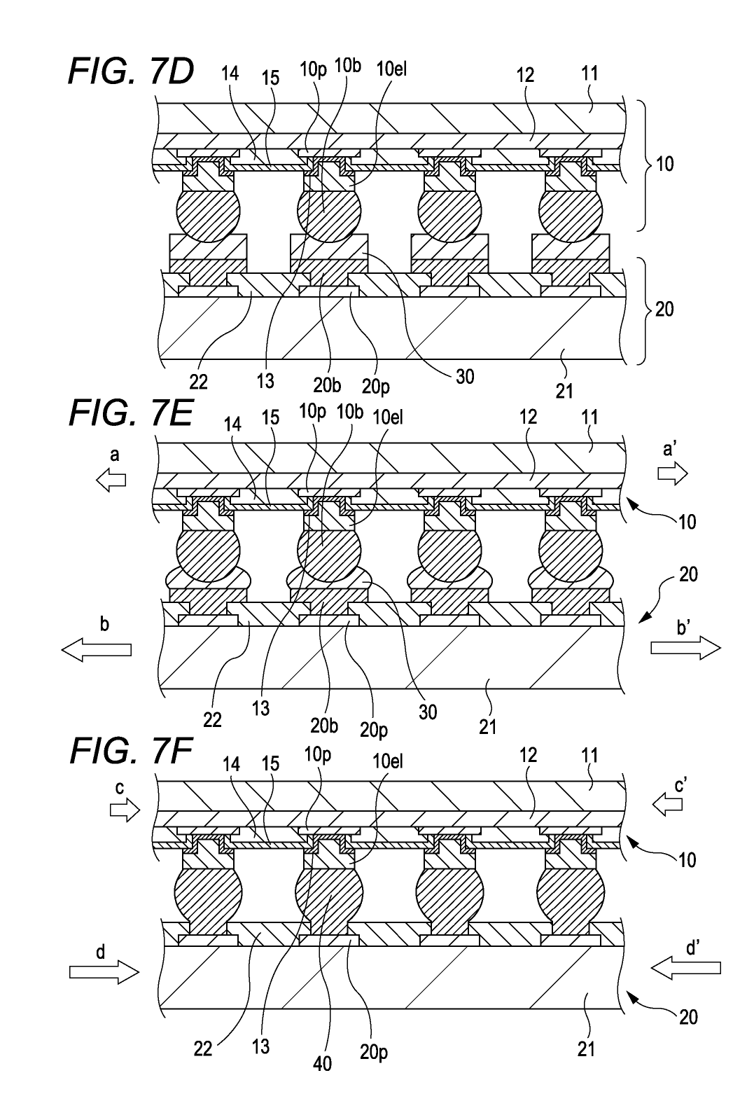

A semiconductor device producing method of the seventh embodiment according to the invention will be described with reference to FIGS. 7A-7F. First the electrode pad 20p of the circuit board 20 is coated with the tinning 20b, and a metallic mask member 52 is disposed on the circuit board 20. FIG. 7A illustrates the state in which the metallic mask member 52 is disposed on the circuit board 20.

In the mask member 52, throughholes 52h are made by patterning in order to selectively dispose the solder pastes 30. Then the throughhole 52h of the mask member 52 is filled with the solder paste 30 by screen printing. FIG. 7B illustrates the state in which the throughhole 52h is filled with the solder paste 30.

Then the mask member 52 is separated from the circuit board 20 to provide the solder paste 30 in the surface of the tinning 20b. FIG. 7C illustrates the state in which the solder paste 30 is provided in the surface of the tinning 20b.

A pasty solder material in which the solder particles having the particle diameters of 10 μm or less are kneaded in the flux material is used as the solder paste 30.

The solder particle may be made of any of the tin (Sn)-bismuth (Bi) solder of the lead (Pb)-free binary solder and the tin (Sn)-bismuth (Bi)-silver (Ag) solder of the lead (Pb)-free ternary solder. The solder particle has, fir example, a melting point of 130° C. to 150° C.

Thus, the semiconductor element 10 is mounted on the circuit board 20 by the so-called flip-chip connection method. The circuit board 20 is coated with the solder material having the melting point of 130° C. to 150° C. on the tinning 20b provided on each electrode pad 20p.

As illustrated in FIG. 7D, the semiconductor element 10 is placed while the bump electrode 10b of the semiconductor element 10 is in contact with the solder paste 30 disposed on the tinning 20b. The electrode pad 20p disposed on the circuit board 20 is coated with the tinning 20b.

While the semiconductor element 10 is placed on the circuit board 20, the semiconductor element 10 is heated by the heating unit provided in the support table (not illustrated) that supports the circuit board 20, thereby performing the reflow treatment to the solder particles included in the solder paste 30.

At this point, the heating treatment temperature in the reflow treatment is set to a temperature at which only the solder particles included in the solder paste 30 are melted.

That is, the heating treatment temperature is set to a temperature that is equal to or more than the melting points of the solder particles included in the solder paste 30 and is lower than the melting points of the bump electrode 10b and tinning 20b, and, for example, the heating treatment temperature is set to 150° C. to 170° C. The time necessary for the reflow treatment is set, for example, to 30 seconds to 3 minutes.

As illustrated in FIG. 7E, the semiconductor element 10 is expanded in the directions of the arrows a and a′ parallel to the principal surface of the semiconductor substrate 11 by the heating in the solder reflow treatment. The arrow a and the arrow a′ are opposite to each other.

On the other hand, the circuit board 20 is expanded in the directions of the arrows b and b′ parallel to the principal surface of the insulating base 21. The arrow b and the arrow b′ are opposite to each other.

At this point, the semiconductor element 10 differs from the circuit board 20 in the expanded amount based on the difference in thermal expansion coefficient. In FIG. 7E, the difference in expanded amount is expressed by the length of the arrow.

That is, the circuit board 20 is expanded larger than the semiconductor element 10 in the direction parallel to the principal surface of the semiconductor element 10.

However, the heating temperature at that time is lower than the melting points of the bump electrode 10b and tinning 20b, and large stress concentration is not generated to the semiconductor element 10.

The solder particles included in the solder paste 30, the bump electrode 10b, and the tinning 20b diffuse mutually by sustaining the solder reflow treatment, so that the solder particles, the bump electrode 10b, and the tinning 20b are integrated as the bump 40 as illustrated in FIG. 7F.

Therefore, the electrode 10el of the semiconductor element 10 and the electrode pad 20p of the circuit board 20 are mechanically connected through the bump 40, and the semiconductor element 10 is flip-chip mounted on the circuit board 20.

That is, the semiconductor element 10 and the circuit board 20 may be electrically connected.

In a process for cooling the semiconductor element 10 to room temperature (for example, 25° C.) after the solder reflow treatment, the semiconductor element 10 is contracted in the directions of the arrows c and c′ parallel to the principal surface of the semiconductor substrate 11. The arrow c and the arrow c′ are opposite to each other.

The circuit board 20 is contracted in the directions of the arrows d and d′ parallel to the principal surface of the insulating base 21. The arrow d and the arrow d′ are opposite to each other.

At this point, the semiconductor element 10 differs from the circuit board 20 in the contracted amount based on the difference in thermal expansion coefficient. In FIG. 7F, the difference in contracted amount is expressed by the length of the arrow.

That is, the circuit board 20 is contracted larger than the semiconductor element 10 in the direction parallel to the principal surface of the semiconductor element 10.

However, the temperature is changed at that time from the melting temperatures of the solder particles included in the solder paste 30 to the room temperature, and large stress concentration is not generated to the semiconductor element 10.

In the producing method of the seventh embodiment, the heating temperature is lowered in the solder reflow treatment in the process for flip-chip mounting the semiconductor element 10 on the circuit board 20, so that the amount of stress applied to the semiconductor element 10 may be reduced.

Therefore, the stress concentration to the low-dielectric insulating layer 12 may be reduced and suppressed in the semiconductor element 10, and the breakage or peel-off of the low-dielectric insulating layer 12 may be prevented.

The reflow treatment may be performed with a dedicated reflow apparatus.

After the semiconductor element 10 is flip-chip mounted on the circuit board 20, the gap between the semiconductor element 10 and the circuit board 20 may be filled with the sealing resin called the underfill material (not illustrated).

Alternatively, the semiconductor element 10 may be coated to perform the resin sealing treatment (not illustrated).

The solder ball constituting the external connection terminal is provided in the other principal surface (backside) of the circuit board 20 to form the semiconductor device having the BGA (Ball Grid Array) structure.

In cases where the large circuit board is used to mount plural semiconductor elements on the circuit board, the resin sealing treatment is collectively performed to the plural semiconductor elements, and the external connection terminal is provided. Then, the wiring board and the sealing resin that is provided on the wiring board to cover the semiconductor element therewith are cut in the thickness direction to form the pieces of semiconductor devices.

In the seventh embodiment, when the semiconductor element 10 in which the bump electrode 10b is provided in the principal surface is mounted on the circuit board 20 by the flip-chip bonding method, the solder paste 30 adheres previously to the tinning 20b that is provided on the electrode pad 20p of the circuit board 20.

The semiconductor element 10 is placed on the circuit board 20 while the bump electrode 10b of the semiconductor element 10 and the tinning 20b are caused to face each other with the solder paste 30 interposed therebetween.

Then the solder particles in the solder paste 30 are melted to integrate the bump electrode 10b, the solder particles, and the tinning 20b.

Therefore, the electrode of the semiconductor element 10 and the electrode pad of the circuit board 20 are mechanically connected through the bump 40, and the semiconductor element 10 is flip-chip mounted on the circuit board 20.

In the semiconductor device producing method of the seventh embodiment, only the solder particles that has the relatively low melting point in the lead (Pb)-free solder and included in the solder paste 30 may be melted to easily integrate the pieces of high-melting-point solder (bump electrode 10b and tinning 20b).

That is, the connecting member including the low-melting-point solder is interposed between the pieces of high-melting-point solder, and the reflow treatment is performed near the melting point of the low-melting-point solder, so that the reflow treatment temperature may be lowered compared with the case in which the pieces of high-melting-point solder are directly melted and joined.

When the semiconductor element 10 and the circuit board 20 are heated to the reflow treatment temperature, and when the semiconductor element 10 and the circuit board 20 are cooled from the reflow treatment temperature to room temperature, the temperature changes of the semiconductor element 10 and the circuit board 20 become smaller compared with the case in which the pieces of high-melting-point solder are directly melted and joined.

A strong stress is not applied to the semiconductor element 10, thereby preventing the stress concentration to the insulating layer formed in the principal surface of the semiconductor element 10.

Even if the low-dielectric insulating layer is used as the insulating layer, the breakage or peel-off of the low-dielectric insulating layer is avoided, and the short circuit or disconnection of the wiring layer and inter-layer connection portion that are provided in the low-dielectric insulating layer is prevented.

Thus, in the seventh embodiment, the high-reliability semiconductor device may be produced with a high production yield.

Further, in the seventh embodiment, the solder paste 30 is disposed in the electrode on the wiring board with the tinning 20b interposed therebetween, so that the coating of the bump electrode 10b of the semiconductor element 10 with the solder paste 30 or solder member 31 may be neglected to simplify the electrode portion forming process in the semiconductor element.

On the other hand, the electrode pad 20p on the circuit board 20 may be coated with the solder paste 30 irrespective of the process for forming the electrode portion of the semiconductor element 10, for example, the electrode pad 20p may be coated with the solder paste 30 in parallel with the process for forming the electrode portion of the semiconductor element 10.

Accordingly, the time necessary to produce the semiconductor device may be shortened.

In the first to seventh embodiments, the tinning treatment (provision of the tinning 20b) is performed to the electrode pad 20p on the circuit board 20. However, as long as good wettability is ensured between the electrode pad 20p and the solder material used in the connecting member and/or the bump electrode 10b, it is not always necessary to perform the tinning treatment.

The melting point of the tinning 20b is not limited to the melting point (210° C. to 220° C.) as long as the tinning 20b has the melting point higher than the melting point of the connecting member.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that various changes, substitutions, and alterations could be made hereto without departing from the spirit and scope of the invention.

What is claimed is:

1. A method for manufacturing a semiconductor device, comprising mounting a semiconductor element on a circuit board, the semiconductor element having a first electrode made of a first material on a semiconductor substrate, the circuit board having a second electrode made of a second material on an insulating substrate, the method comprising:
forming a connecting member on the first electrode, a melting point of the connecting member being lower than a melting point of the first material;
placing the semiconductor element on the circuit board, so as to face the connecting member toward the second electrode; and
connecting the first electrode and the second electrode, so as to interpose the connecting member between the first electrode and the second electrode, at a temperature that is lower than the melting point of the first material and higher than the melting point of the connecting member.

2. The method for manufacturing a semiconductor device according to claim 1,
wherein the connecting member is made of a solder paste including a solder particle in a flux material.

3. The method for manufacturing a semiconductor device according to claim 2,
wherein the first electrode is a bump electrode.

4. The method for manufacturing a semiconductor device according to claim 3,
wherein the connecting member is a film, and the film is formed on the first electrode by bringing the bump electrode in contact with the solder paste.

5. The method for manufacturing a semiconductor device according to claim 3,
wherein the connecting member is a film, and the film is formed on the first electrode by dipping the bump electrode into the solder paste while the solder paste is in a melted state.

6. The method for manufacturing a semiconductor device according to claim 1,
wherein a flux material is applied onto the connecting member after forming the connecting member on the first electrode.

7. The method for manufacturing a semiconductor device according to claim 1, further comprising,:
forming a second connecting member on the second electrode, wherein a melting point of the second connecting member is lower than a melting point of the connecting member before connecting the first electrode and the second electrode.

8. The method for manufacturing a semiconductor device according to claim 7,
wherein the second connecting member is made of a solder paste including a solder particle in a flux material.

9. The method for manufacturing a semiconductor device according to claim 1,
wherein the first material contains any of Sn—Cu, Sn—Ag, Sn—Ag—Cu, Sn—Ag—Cu—Bi, Sn—Ag—In, Sn—Ag—In—Bi, Sn—Zn, and Sn—Zn—Bi.

10. The method for manufacturing a semiconductor device according to claim 1,
wherein the connecting member contains any of Sn—Bi and Sn—Bi—Ag.
